(19) United States
(12) Patent Application Publication
(10) Pub. No.: US 2010/0019269 A1
(43) Pub. Date: Jan. 28, 2010

(54) LIGHT-EMITTING DEVICE AND METHOD OF MANUFACTURING THE SAME

(76) Inventors: Tae-Geun KIM, SEONGNAM-SI, (KR); Byoung-Gyu LEE, SEOUL (KR)

Correspondence Address: IPLA P.A., 3580 WILSHIRE BLVD., 17TH FLOOR, LOS ANGELES, CA, 90010, US

(21) Appl. No.: 12/392,957

(22) Filed: Feb. 25, 2009

(30) Foreign Application Priority Data
Jul. 25, 2008 (KR) 10-2008-0072616

(51) Int. Cl. H01L 33/00

(52) U.S. Cl. 257/99; 438/22; 257/E33.062

(57) ABSTRACT

A light-emitting device and method of manufacturing the same provides a substrate, a semiconductor layer formed on the substrate and configured to generate light, and a transparent electrode layer formed on the semiconductor layer and configured to transmit the light generated from the semiconductor layer. The amount of a material of which the transparent electrode layer is made decreases gradually as it goes from the bottom to the top.

### CROSS REFERENCES

Applicant claims foreign priority under Paris Convention and 35 U.S.C. §119 to Korean Patent Application No. 10-2008-0072616, filed Jul. 25, 2008 with the Korean Intellectual Property Office, where the entire contents are incorporated herein by reference.

### BACKGROUND OF THE INVENTION

1. Field of the Invention

The present invention relates to a light-emitting device and a method of manufacturing the same, and more particularly, to a light-emitting device and a method of manufacturing the same, which is capable of improving light extraction efficiency by forming a transparent electrode layer having reduced total reflection.

2. Background of the Related Art

GaN-based Light-Emitting Diodes (LEDs) for emitting blue, green, and UV rays are being increasingly used in the entire society, such as an indicator, the backlight of a Liquid Crystal Device (LCD), and the backlight of a mobile phone keypad as well as small-sized or large-sized signboards.

The existing signal lamps are replaced by bluish green LEDs, and a variety of LEDs are being used as light sources for vehicles and indirect illuminations. It is expected that, if white LEDs having higher light efficiency are developed, the existing electric lamps will be replaced by the white LEDs.

In order to fabricate the LEDs used in various fields as described above, a thin film is formed on a sapphire substrate or an SiC substrate using a method, such as Metal Organic Chemical Vapor Deposition (MOCVD), thereby forming the LED made of GaN material.

FIGS. 1A and 1B are diagrams showing a conventional method of fabricating a light-emitting device. Referring to FIGS. 1A and 1B, in the conventional method, a buffer layer (un-doped GaN) 12 is formed on a substrate 11, made of a sapphire, SiC, or GaN, using a MOCVD method. An n-GaN layer 13, an active layer (InₓGa₁₋ₓN(x=0˜1)) 14, and a p-GaN layer 15 are sequentially formed on the buffer layer 12 (refer to (a) of FIG. 1A).

In order to activate the impurities of the p-GaN layer 15, annealing is performed on the p-GaN layer 15 at a temperature of about 600° C. for about 20 minutes. In order to form an n-type electrode, etching is downward performed from the p-GaN layer 15 so that a part of the n-GaN layer 13 is exposed (refer to (b) of FIG. 1A).

Metal for ohmic contact (or a transparent conducting thin film 16) is formed on the entire surface of the p-GaN layer 15 (refer to (c) of FIG. 1A). A p-type ohmic contact 17 for a pad is formed on the transparent conducting thin film 16 for bonding purpose when a chip is assembled (refer to (d) of FIG. 1B).

An electrode layer 18, used as both ohmic contact and pad metal, is formed on the etched n-GaN layer 13, thereby completing a chip (refer to (e) of FIG. 1B).

The completed LED chip is formed in the form of a Surface Mount Device (SMD), a lamp, or a high-output LED package through packaging and molding processes.

A process of driving the LED is described below. When voltage is applied to the LED through the N and p-type electrodes, electrons and holes are introduced from the n-GaN layer 13 and the p-GaN layer 15 to the active layer 14. The electrons and the holes are combined in the active layer 14, thereby emitting light.

The light emitted from the active layer 14 travels up and down on the basis of the active layer 14. The upward traveling light is emitted outside through the transparent electrode thinly formed on the p-GaN layer 15. Part of the downward traveling light is emitted outside the chip, and the remaining thereof travels downward on the basis of the substrate and is then absorbed by or reflected from a solder which is used when the LED chip is assembled. The downward traveling light then travels upward again. Part of the downward traveling light is absorbed by the active layer 14 and the remaining thereof is emitted outside the chip through the transparent electrode via the active layer 14.

In order to implement different wavelengths using this LED chip, colors of multiple wavelengths are implemented by forming phosphor (i.e., wavelength conversion material) on the LED chip when the chip is assembled. Accordingly, a white LED having specific wavelengths or a mixed wavelength and having a converted wavelength can be implemented.

The above-described LED uses the transparent electrode formed of a single layer and has the following problems.

A transparent electrode is advantageous in that it has the light transmittance of about 90%, whereas a transparent electrode formed of a single layer is problematic in that it has low light extraction efficiency because it transmits only the light of a limited incident angle because of the difference in the refractive index between the transparent electrode and a neighbor layer, such as a p-GaN layer and an air layer.

In more detail, when light emitted from the active layer of the GaN LED passes through the transparent electrode via the p-GaN layer, only the light of a limited incident angle passes through the transparent electrode according to Snell's Law owing to the difference in the refractive index (between the p-GaN layer=2.4 and the transparent electrode layer (ITO)=2.0) at the interface of the p-GaN layer and the transparent electrode layer.

Furthermore, the refractive index of the transparent electrode layer 16 is about 2.0. Accordingly, in the case where light exits to the air (the refractive index=1.0) layer via the transparent electrode layer 16 as shown in FIG. 2, when the incident angle of the light is smaller than a critical angle (Θ), the light exists to the outside through the transparent electrode layer 16 \textcircled{1} of FIG. 2). However, when the incident angle of the light is greater than the critical angle (Θ) (\textcircled{2} and \textcircled{3} of FIG. 2), the light is totally reflected at the interface face of the transparent electrode layer 16 and the air layer according to Snell's Law. Consequently, a problem arises because the amount of light extracted is significantly reduced.

In order to solve the above problem, another conventional technological solution has proposed a method of forming a transparent electrode layer and making coarse the surface of the transparent electrode layer by arbitrarily etching the surface, as shown in FIG. 3. Accordingly, light extraction efficiency is improved by reducing total reflection at the interface between the transparent electrode layer and external air (or epoxy).

The above conventional method is however problematic in that the surface of a device is damaged because an etching process of forming patterns in the device surface must be performed and the properties or the lifespan of an optical device are adversely affected.

### SUMMARY OF THE INVENTION

Therefore, the present invention has been made in view of the above problems, and it is an object of the present invention to provide a light-emitting device having improved light extraction efficiency as compared with a conventional light-emitting device, and a method of manufacturing the same.

In order to achieve the above object, in one aspect, the present invention provides a light-emitting device, including: a substrate; a semiconductor layer formed on the substrate and configured to generate light; and a transparent electrode layer formed on the semiconductor layer and configured to transmit the light generated from the semiconductor layer. Here, the amount of a material of which the transparent electrode layer is made decreases gradually as it goes from the bottom to the top.

Also, the transparent electrode layer may be formed such that a size of each of air gaps included in the transparent electrode layer gradually increases as it goes fro the bottom to the top.

In addition, the transparent electrode layer may comprise a plurality of sub-transparent electrode layers, and a size of each of air gaps included in each of the sub-transparent electrode layers may increase as it goes from the semiconductor layer to the top.

In the meantime, to achieve the above object, in another aspect, the present invention provides a method of manufacturing a light-emitting device, comprising the steps of: (a) forming a semiconductor layer for generating light on a substrate and; (forming a transparent b) electrode layer on the semiconductor layer so that an amount of material constituting the transparent electrode layer gradually decreases.

Also, the step (b) comprises the steps of: (b1) arranging polymer beads on the semiconductor layer and reducing a size of each of the polymer beads, and then forming a sub-transparent electrode layer in which the polymer beads are included; (b2) forming air gaps in the sub-transparent electrode layer by removing the polymer beads; and (b3) forming the transparent electrode layer, including a plurality of sub-transparent electrode layers, on the sub-transparent electrode layer by repeatedly performing the steps (b1) and (b2).

Besides, the step (b1) may include decreasing the size of each of the polymer beads by etching the polymer beads.

Further, the step (b2) may include removing the polymer beads by performing a burning process.

Also, the step (b3) may include decreasing the size of each of the polymer beads so that a size of each of the air gaps formed in an upper sub-electrode layer is larger than a size of each of the air gaps formed in a lower sub-electrode layer.

### BRIEF DESCRIPTION OF THE DRAWINGS

FIGS. 1A to 1E are diagrams showing a conventional method of manufacturing a light-emitting device;

FIGS. 2 is a diagram showing the problems of light extraction efficiency, occurring in the conventional light-emitting device;

FIG. 3 is a diagram showing a transparent electrode layer formed by known methods;

FIGS. 4A to 4D are diagrams showing a method of forming a transparent electrode layer according to an embodiment of the present invention;

FIG. 5 is a diagram showing the structure of the transparent electrode layer formed according to an embodiment of the present invention and effects thereof; and

FIG. 6 is a diagram showing the structure of a light-emitting device formed according to an embodiment of the present invention and a light extraction effect thereof.

### DETAILED DESCRIPTION OF THE EMBODIMENT

The embodiments of the invention will be hereinafter described in detail with reference to the accompanying drawings.

According to the present invention, air gaps are formed in a transparent electrode layer. Here, the amount of material constituting the transparent electrode layer decreases and the size of each of air gaps increases in a direction from a second semiconductor layer (a p-GaN layer) towards an ohmic contact so that a total refractive index gradually decreases. Accordingly, the second semiconductor layer (a p-GaN layer) has a refractive index lower than that of the transparent electrode layer, and the difference in the refractive index between air or phosphor material, coming in contact with the transparent electrode layer, and the transparent electrode layer can be reduced. Consequently, light extraction efficiency can be improved.

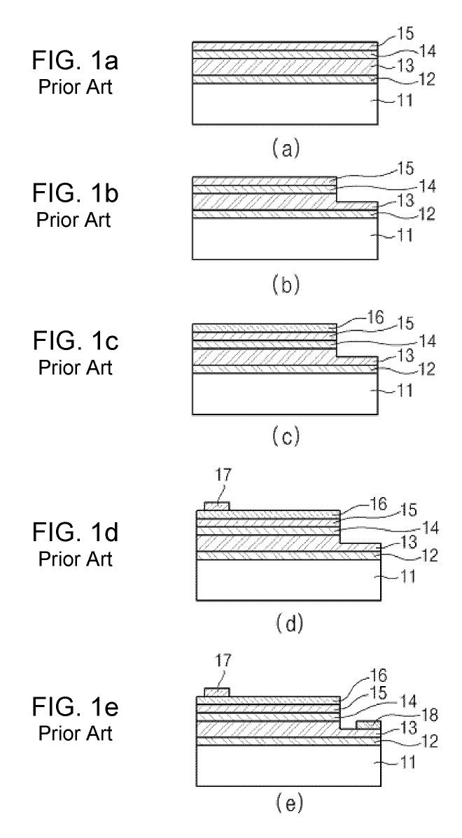

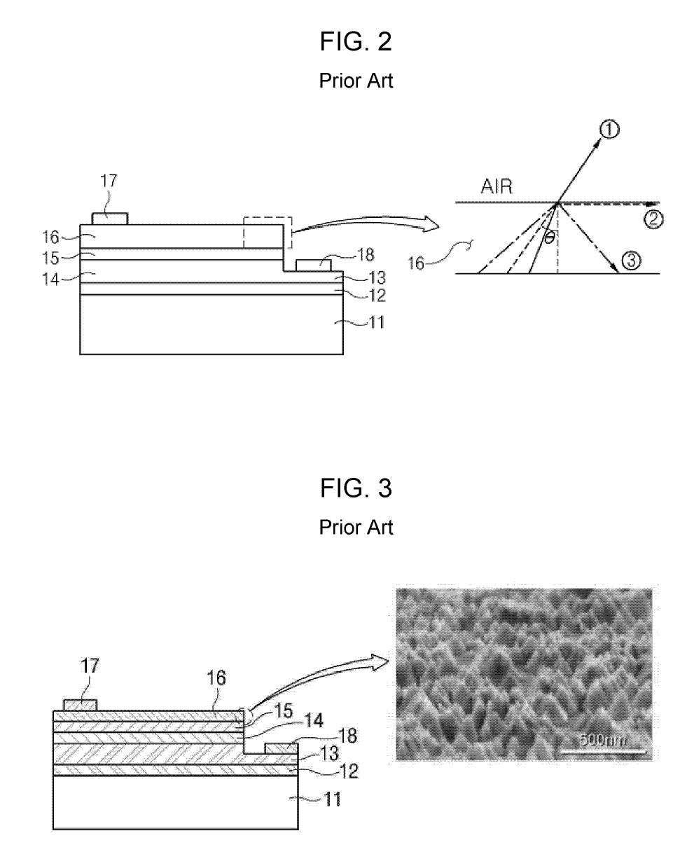

Processes other than the process of forming the transparent electrode layer are the same as the above processes described with reference to FIGS. 1A and 1B. Accordingly, a construction for forming the transparent electrode layer is for the most part described in connection with some embodiments of the present invention.

Some embodiments of the present invention are described below with reference to the accompanying drawings.

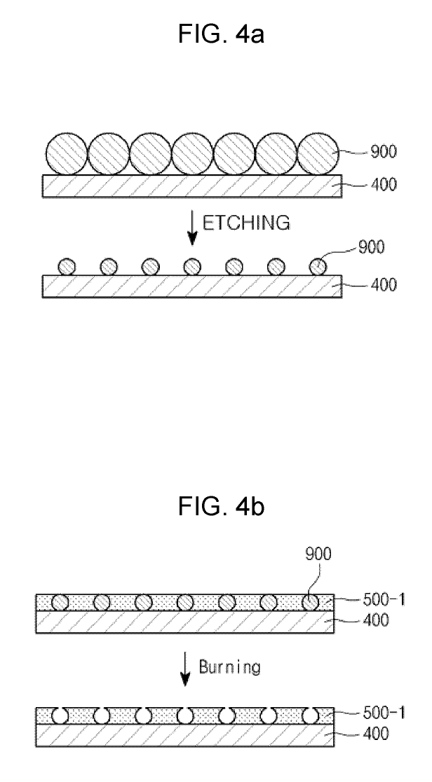

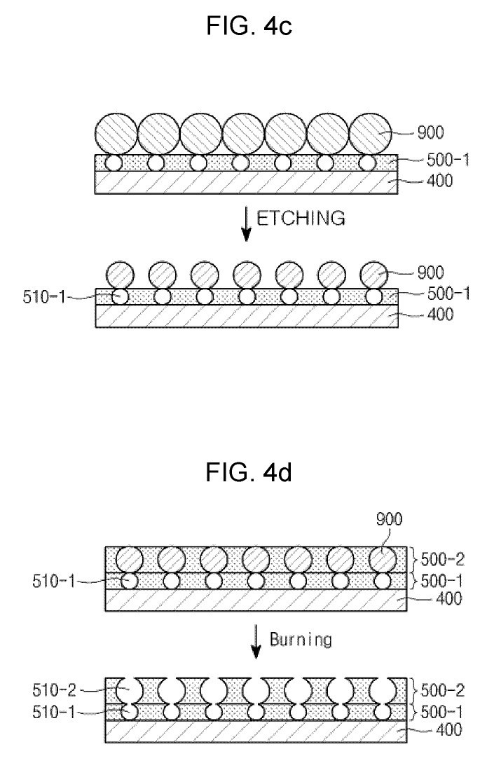

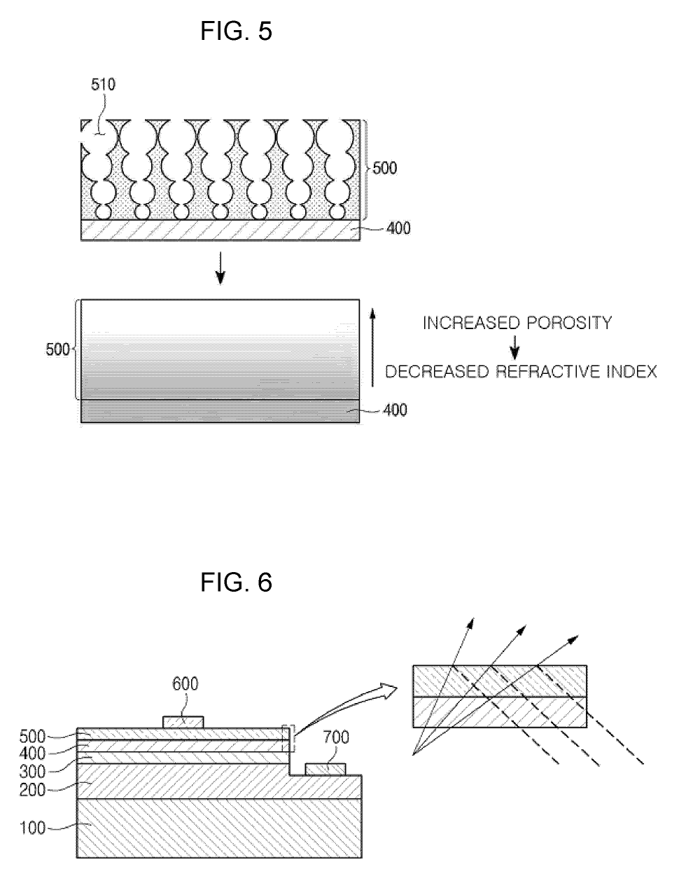

FIGS. 4A to 4D are diagrams showing a method of forming a transparent electrode layer according to an embodiment of the present invention, FIG. 5 is a diagram showing the structure of the transparent electrode layer formed according to an embodiment of the present invention and effects thereof, and FIG. 6 is a diagram showing the structure of a light-emitting device formed according to an embodiment of the present invention and a light extraction effect thereof.

In order to manufacture the light-emitting device of the present invention, a buffer layer (un-doped GaN (not shown)), a first semiconductor layer (an n-GaN layer) 200, an active layer 300, and a second semiconductor layer (a p-GaN layer) 400 are sequentially formed on a substrate 100, made of a sapphire, SiC, or GaN, as shown in FIG. 1A.

In order to form an electrode, etching is downward performed on the first semiconductor layer (the n-GaN layer) 200 from the second semiconductor layer (the p-GaN layer) 400 so that part of the first semiconductor layer (the n-GaN layer) 200 is exposed. It is to be noted that the process of forming the electrode may be performed after a transparent electrode layer has been formed.

As shown in FIG. 4A, after polymer beads 900 are mixed with an organic solvent, the mixed results are coated on the second semiconductor layer (the p-GaN layer) 400 through spin-coating. The types of the polymer beads 900 may include polystyrene, latex, and silica-based material. Each of the polymer beads 900 may be 50 nm˜2 μm in diameter.

In this case, an opal matrix in which the polymer beads 900 are arranged on the second semiconductor layer (the p-GaN layer) 400 in the form of a single layer may be formed by properly controlling the spin coating speed (rpm). Here, the spin coating speed (rpm) may be properly set depending on the size of each of the polymer beads 900. In the case where the polymer beads each having a diameter of 300 nm, 3000 rpm may be appropriate.

After the polymer beads 900 are arranged on the second semiconductor layer 400 in the form of a single layer, the size of each of the polymer beads 900 is reduced by etching the polymer beads 900 as shown at the lower side of FIG. 4A. Here, the etching method may include wet etching, dry etching, or Reactive Ion Etching (RIE) depending on the type of the polymer beads 900. For example, in the case where polystyrene beads 900 are used, RIE may be used. In this case, the size of each of the polystyrene beads 900 etched may be controlled by controlling an etching execution time.

After the size of each of the polymer beads 900 is reduced to a desired size through etching, material for forming a transparent electrode layer is formed in the opal matrix, constructed with the polymer beads 900, using a method, such as dip coating, spin coating, or electroplating, thereby forming a first sub-transparent electrode layer 500-1, as shown at the upper side of FIG. 4B.

The first sub-transparent electrode layer 500-1 of a reverse opal matrix in which air gaps 510-1 are formed is formed by removing the polymer beads 900 in the first sub-transparent electrode layer 500-1, as shown at the lower side of FIG. 4B. In some embodiments of the present invention, the first sub-transparent electrode layer 500-1 of a reverse opal matrix having the air gaps 510-1 formed therein may be formed by removing the polymer beads 900 in the first sub-transparent electrode layer 500-1 through a burning process performed at a temperature of 260° C. or more, as shown at the lower side of FIG. 4B.

After the first sub-transparent electrode layer 500-1, including the air gaps, is formed, the same process as that shown in FIG. 4A is performed. In other words, as shown in FIG. 4C, a polymer beads solution mixed with an organic solvent is coated on the first sub-transparent electrode layer 500-1, including the air gaps 510-1, through spin-coating. After the polymer beads 900 are arranged on the first sub-transparent electrode layer 500-1, the size of each of the polymer beads 900 is reduced by etching the polymer beads 900, as shown at the lower side of FIG. 4C. Here, the size of each of the polymer beads 900 after the etching must be larger than that of each of the air gaps 510-1 (the size of each of the polymer beads after the etching in the previous step), included in the underlying first sub-transparent electrode layer 500-1.

After the size of each of the polymer beads 900 is reduced to a desired size through the etching, material for forming a transparent electrode layer is formed in the opal matrix constructed with the polymer beads 900 using a method, such as dip coating, spin coating, or electroplating, thereby forming a second sub-transparent electrode layer 500-2 on the first sub-transparent electrode layer 500-1, as shown at the upper side of FIG. 4D. Air gaps 510-2 are formed in the second sub-transparent electrode layer 500-2 by removing the polymer beads 900 included in the second sub-transparent electrode layers 500-2 through a burning process, as shown at the lower side of FIG. 4D. Here, the size of each of the gaps 510-2 formed in the second sub-transparent electrode layer 500-2 is larger than that of each of the air gaps 510-1 formed in the first sub-transparent electrode layer 500-1.

Next, a transparent electrode layer 500, constructed of a number of sub-transparent electrode layers, is formed by repeatedly performing the same process as above while the time taken to etch the polymer beads 900 is gradually decreased (that is, while the size of each of the polymer beads is gradually increased), as shown in FIG. 5. Here, the size of the air gaps, included in the transparent electrode layer 500, gradually increases upward.

Therefore, in the transparent electrode layer 500, the amount of material constituting the transparent electrode layer gradually decreases and the size of each of the air gaps 510 gradually increases as it goes from the bottom to the top. Accordingly, it can be seen from FIG. 5 that the refractive index of the transparent electrode layer gradually decreased upward.

The relationship between the size of the air gaps in the transparent electrode layer and the refractive index can be expressed in the following Equation 1.

$$Porosity = ( 1 - \frac{{n}^{2} - 1}{{n}_{0}^{2} - 1} ) χ 100 ( \% ) \qquad Equation 1$$

where n is the refractive index of a thin film

In Equation 1, no denotes the refractive index of an air layer and n denotes the refractive index of a transparent electrode layer.

If the transparent electrode layer 500 is formed through the above process, the top surface of the transparent electrode layer 500 coming in contact with external air or phosphor material has a refractive index which is almost the same as the refractive index (n=1) of air. Accordingly, as shown in FIG. 5, light introduced from the second semiconductor layer 400 to the transparent electrode layer 500 is not reflected as indicated by a dotted line, but is chiefly emitted outside. Consequently, there is an advantage in that light extraction efficiency can be increased.

As described above, according to the present invention, the transparent electrode layer is formed such that the refractive index of the transparent electrode layer of the light-emitting device gradually decreases upward and the difference in the refractive index between the transparent electrode layer and air, etc. at the interface of the transparent electrode layer and air is minimized. Accordingly, since light generated from the active layer is totally reflected at the interface between the transparent electrode layer and air, the amount of light introduced into the light-emitting device again can be minimized, and light extraction efficiency can be improved.

In more detail, according to the present invention, in order to form a transparent electrode layer, polymer beads are arranged in the form of a single layer. The size of each of the polymer beads is controlled by performing an etching process. Material constituting the transparent electrode layer is filled between the polymer beads. The polymer beads are then removed through a burning process, thereby forming air gaps in the transparent electrode layer. Next, in the same manner, a transparent electrode layer, including air gaps larger than the air gaps formed in the previous transparent electrode layer, are formed on the previous transparent electrode layer. A transparent electrode layer, including air gaps larger than the air gaps formed in the transparent electrode layer formed as described above, are formed. This process is repeatedly performed. Consequently, the transparent electrode layer having multiple layers is formed such that the size of each of the air gaps increases and the amount of material constituting the transparent electrode layer decreases from a lower layer to an upper layer, thereby lowering the refractive index.

Here, if the size of each of the air gaps corresponding to the respective polymer beads is minutely controlled by finely controlling the size of each of the polymer beads, the transparent electrode layer, having a refractive index which almost consecutively changes, can be formed. Accordingly, total reflection generated at the interface between the transparent electrode layer and the air layer can be minimized because, with the fact that the refractive index of the air layer is about 1.0 taken into consideration, a critical angle at which total reflection is generated is increased when light travels through the interface. There is another advantage in that light extraction efficiency can be improved because light generated from the active layer of a light-emitting device can be more efficiently emitted outside, as compared with a conventional light-emitting device.

Furthermore, according to the present invention, the transparent electrode layer is formed using a mixing/coating method, not the existing deposition method, through a Sol-gel method or an electroplating method instead of a sputtering or e-beam deposition method conventionally used to form a transparent electrode layer. Thus, the transparent electrode layer can be formed at a relatively low temperature. Accordingly, when the transparent electrode layer is formed, shock applied to the semiconductor layer (the p-GaN layer) can be reduced, and defects occurring at the interface between the semiconductor layer (the p-GaN layer) and the transparent electrode layer can be reduced. Furthermore, the Sol-gel method is excellent in terms of the manufacturing expenses, the manufacturing process, and stability as compared with the existing e-beam deposition or sputtering method. Accordingly, there are advantages in that a light-emitting device having excellent light extraction efficiency can be manufactured more cheaply and stably.

While the present invention has been described with reference to the particular preferred embodiments, it will be understood by those skilled in the art that various modifications and variations can be made to the present invention without departing from the spirit and scope of the appended claims. Therefore, the disclosed embodiments should be considered in view of explanation, but no limitation. The technical scope of the present invention is taught in the claims, but not the detailed description, and all the differences in the equivalent scope thereof should be construed as falling within the present invention.

What is claimed is:

1. A light-emitting device, comprising:
a substrate;
a semiconductor layer formed on the substrate and configured to generate light; and
a transparent electrode layer formed on the semiconductor layer and configured to transmit the light generated from the semiconductor layer,
wherein the amount of a material of which the transparent electrode layer is made decreases gradually as it goes from the bottom to the top.

2. The light-emitting device according to claim 1, wherein:
the transparent electrode layer comprises a plurality of sub-transparent electrode layers, and
a size of each of air gaps included in each of the sub-transparent electrode layers increases as it goes from the semiconductor layer to the top.

3. The light-emitting device according to claim 1, wherein a size of each of air gaps included in the transparent electrode layer gradually increases as it goes fro the bottom to the top.

4. The light-emitting device according to claim 3, wherein:
the transparent electrode layer comprises a plurality of sub-transparent electrode layers, and
the size of each of the air gaps included in each of the sub-transparent electrode layers increases as it goes from the semiconductor layer to the top.

5. A method of manufacturing a light-emitting device, comprising the steps of:
(a) forming a semiconductor layer for generating light on a substrate; and
(b) forming a transparent electrode layer on the semiconductor layer so that an amount of material constituting the transparent electrode layer gradually decreases.

6. The method according to claim 5, wherein the step (b) comprises the steps of:
(b1) arranging polymer beads on the semiconductor layer and reducing a size of each of the polymer beads, and then forming a sub-transparent electrode layer in which the polymer beads are included;
(b2) forming air gaps in the sub-transparent electrode layer by removing the polymer beads; and
(b3) forming the transparent electrode layer, including a plurality of sub-transparent electrode layers, on the sub-transparent electrode layer by repeatedly performing the steps (b1) and (b2).

7. The method according to claim 6, wherein the step (b3) includes decreasing the size of each of the polymer beads so that a size of each of the air gaps formed in an upper sub-electrode layer is larger than a size of each of the air gaps formed in a lower sub-electrode layer.

8. The method according to claim 6, wherein the step (b1) includes decreasing the size of each of the polymer beads by etching the polymer beads.

9. The method according to claim 8, wherein the step (b3) includes decreasing the size of each of the polymer beads so that a size of each of the air gaps formed in an upper sub-electrode layer is larger than a size of each of the air gaps formed in a lower sub-electrode layer.

10. The method according to claim 6, wherein the step (b2) includes removing the polymer beads by performing a burning process.

11. The method according to claim 10, wherein the step (b3) includes decreasing the size of each of the polymer beads so that a size of each of the air gaps formed in an upper sub-electrode layer is larger than a size of each of the air gaps formed in a lower sub-electrode layer.
